(19) United States
(12) Patent Application Publication
(10) Pub. No.: US 2008/0088320 A1
(43) Pub. Date: Apr. 17, 2008

(54) Network measuring and apparatus for magnitude and phase portion independently

(76) Inventor: Koji Harada, Hyogo (JP)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/986,154

(22) Filed: Nov. 20, 2007

(30) Foreign Application Priority Data
Jun. 29, 2005 (JP) 2005-189837
May 23, 2006 (US) PCT/US2006/019924

(51) Int. Cl. G01R 31/00

(52) U.S. Cl. 324/612

(57) ABSTRACT

Reference demodulated signals are applied to the device under test, or reference modulated signals are generated from the output signals of the device under test; each component of the output signals is generated from the output signals of the device under test; each component of the reference modulated signals is generated from the reference modulated signals; and the network properties of the device under test are analyzed based on the components of the output signals and the components of the corresponding reference modulated signals.

### FIELD OF THE INVENTION

The present invention pertains to technology for analyzing network properties and in particular, relates to technology for analyzing the properties of signal paths related to multiple modulation systems by measuring the signals that have been modulated by the modulation system.

### DISCUSSION OF THE BACKGROUND ART

In recent years there has been a tendency toward the use of polar modulation for mobile telecommunications systems. Polar modulation is a method whereby the signal points in a signal space are represented by amplitude component r and angle component θ (refer to JP Unexamined Patent Application (Kokai) 2005-86,673 and 2004-356,835 and 2004-361,170). The amplitude component is also called the amplitude signal, the absolute value component, or the absolute value signal. The angle component is also called the angle signal, the phase component, or the phase signal. In the present Specification the amplitude component and the angle component are as a whole referred to as polar coordinate components or polar coordinate signals. This polar modulation method can improve the power efficiency of a signal amplifier. Refer to FIG. 1. FIG. 1 is a block diagram showing the concept of the polar modulation method. A polar coordinate signal generator 110 generates an amplitude component r and a phase component θ from digital data. The signals output from a carrier signal source 120 are phase modulated by phase component θ at a phase modulator 130. The phase modulated signals are further amplitude modulated by amplitude component r at a polar modulation amplifier 140. The signals generated in this way by a polar modulation method are called polar modulated signals. A variable-gain saturation amplifier 143 amplitude modulates the output signals of phase modulator 130 by amplitude component r at polar modulation amplifier 140. A low-pass filter 141 and a band-pass filter 142 optimize the related signals.

Phase modulation by phase modulator 130 and amplitude modulation by polar modulation amplifier 140 are not executed correctly unless band-pass filter 141 and low-pass filter 142 are properly adjusted. The properties of band-pass filter 141 and low-pass filter 142 must be known in order to properly adjust band-pass filter 141 and low-pass filter 142. However, once polar modulation amplifier 140 has been assembled as a single unit, it is possible to measure only the input signals to band-pass filter 141, the input signals to low-pass filter 142, and the output signals of polar modulation amplifier 140. Consequently, it is not possible to determine the properties of band-pass filter 141 and low-pass filter 142 with a conventional network analyzer, even if the output signals of polar modulation amplifier 140 are measured.

Therefore, an object of the present invention is to provide a method and an apparatus for analyzing the network properties at specific locations inside a device under test related to specific components of modulated signals or specific modulation systems by measuring signals modulated by multiple modulation systems that are output from a device under test. Another object is to analyze the network properties of filters housed inside a polar modulation amplifier.

### SUMMARY OF THE INVENTION

The first subject of the invention is characterized in that it is a method for analyzing the network properties of a device under test, and in comprising a step for applying reference modulated signals to the device under test or for generating reference modulated signals from the output signals of the device under test; a step for generating each component of the output signals from the output signals of the device under test; a step for generating each component of the reference modulated signals from the reference modulated signals; and a step for analyzing the network properties of the device under test based on the components of the output signals and the components of the corresponding reference modulated signals.

The second subject of the invention is characterized in that it is a method for analyzing the network properties of a device under test, and in that it comprises a step for applying reference modulated signals to the device under test or for generating reference modulated signals from the output signals of the device under test; a step for demodulating the output signals of the device under test by the respective system of N number of one or more different demodulation systems to obtain N number of demodulated signals, which are the demodulation results; a step for demodulating the reference modulated signals by the respective system of the above-mentioned N number of demodulation systems to obtain N number of demodulated signals, which are the demodulation results; and a step for analyzing the network properties of the device under test based on the demodulated signals of the output signals and the demodulated signals of the reference demodulated signals originating from the same demodulation system.

The third subject of the invention is characterized in that the analysis step of the second subject of the invention involves analyzing the network properties of the device under test based on the results of modulating the demodulated signals of the output signals by the modulation system that is paired up with the demodulation system related to the demodulated signals of the output signals and the results of modulating the demodulated signals of the reference modulated signals by the modulation system that is paired up with the demodulation system related to the demodulated signals of the reference modulated signals for at least one demodulation system.

The fourth subject of the invention is characterized in that it is a method for analyzing the network properties of a device under test, and in that it comprises a step for applying reference modulated signals to a device under test or for generating reference modulated signals from the output signals of the device under test; a step for amplitude demodulation of output signals of the device under test and for obtaining amplitude demodulated signals, which are the amplitude component of the output signals; a step for phase demodulation of the output signals and for obtaining phase demodulated signals, which are the phase component of the output signals; a step for amplitude demodulation of the reference modulated signals and for obtaining reference amplitude signals, which are the amplitude component of the reference signals; a step for phase demodulation of the reference modulated signals and for obtaining reference phase signals, which are the phase component of the reference signals; a step for analyzing the network properties of the device under test based on the amplitude demodulated signals and the reference amplitude signals; and a step for analyzing the network properties of the device under test based on the phase demodulated signals and reference phase signals.

The fifth subject of the invention is characterized in that the step for analyzing the network properties of the device under test based on the phase demodulated signals and the reference phase signals of the fourth subject of the invention involves analyzing the network properties of the device under test based on the results of modulating the phase demodulated signals by the phase modulation system that is paired up with the phase demodulation system related to the phase demodulated signals and the results of modulating the reference phase signals by the phase modulation system.

The sixth subject of the invention is characterized in that it is an apparatus for analyzing the network properties of a device under test, and in that it comprises a means for applying reference modulated signals to the device under test or for generating reference modulated signals from the output signals of the device under test; a means for generating each component of the output signals from the output signals of the device under test; a means for generating each component of the reference modulated signals from the reference modulated signals; and a means for analyzing the network properties of the device under test based on the components of the output signals and the components of the corresponding reference modulated signals.

The seventh subject of the invention is characterized in that it is an apparatus for analyzing the network properties of a device under test, and in that it comprises a means for applying reference modulated signals to the device under test or for generating reference modulated signals from the output signals of the device under test; a means for demodulating the output signals of the device under test by the respective system of N number of one or more different demodulation systems to obtain N number of demodulated signals, which are the demodulation results; a means for demodulating the reference modulated signals by the respective system of said N number of demodulation systems to obtain N number of demodulated signals, which are the demodulation results; and a means for analyzing the network properties of the device under test based on the demodulated signals of the output signals and the demodulated signals of the reference demodulated signals originating from the same demodulation system.

The eighth subject of the invention is characterized in that the analysis means of the seventh subject of the invention analyzes the network properties of the device under test based on the results of modulating the demodulated signals of the output signals by the modulation system that is paired up with the demodulation system related to the demodulated signals of the output signals and the results of modulating the demodulated signals of the reference modulated signal by the modulation system that is paired up with the demodulation system related to the demodulated signals of the reference modulated signals for at least one demodulation system.

The ninth subject of the invention is characterized in that it is an apparatus for analyzing the network properties of a device under test, and in that it comprises a means for applying reference modulated signals to a device under test or for generating reference modulated signals from the output signals of the device under test; a means for amplitude demodulation of output signals of the device under test and for obtaining amplitude demodulated signals, which are the amplitude component of the output signals; a means for phase demodulation of the output signals and for obtaining phase demodulated signals, which are the phase component of the output signals; a means for amplitude demodulation of the reference modulated signals and for obtaining reference amplitude signals, which are the amplitude component of the reference signals; a means for phase demodulation of the reference modulated signals and for obtaining reference phase signals, which are the phase component of the reference signals; a means for analyzing the network properties of the device under test based on the amplitude demodulated signals and the reference amplitude signals; and a means for analyzing the network properties of the device under test based on the phase demodulated signals and reference phase signals.

The tenth subject of the invention is characterized in that the means for analyzing the network properties of the device under test based on the phase demodulated signals and the reference phase signals of the ninth subject of the invention analyzes the network properties of the device under test based on the results of modulating the phase demodulated signals by the phase modulation system that is paired up with the phase demodulation system related to the phase demodulated signals and the results of modulating the reference modulated signals by the phase modulation system.

The eleventh subject of the invention is characterized in that by means of any of the first through fifth subjects of the invention, the device under test outputs modulated signals when modulated signals are applied.

The twelfth subject of the invention is characterized in that by means of any of the sixth through tenth subjects of the invention, the device under test outputs modulated signals when modulated signals are applied.

By means of the present invention, it is possible to analyze the network properties of specific locations within a device under test in relationship to specific components or specific modulation systems of modulated signals. It is therefore possible to analyze the network properties of a filter inside a polar modulation amplifier.

### BRIEF DESCRIPTION OF THE DRAWINGS

FIG. 1 is a block diagram showing the concept of polar modulation.

FIG. 2 is a drawing showing a device under test 200 and an electronic measuring apparatus 300.

FIG. 3 is a drawing showing the internal structure of a network property analyzer 440.

FIG. 4A is a drawing showing the waveform of an amplitude component S_{Rr}.

FIG. 4B is a drawing showing the waveform of a phase component S_{Rθ}.

FIG. 5 is a drawing showing a device under test 500 and an electronic measuring apparatus 600.

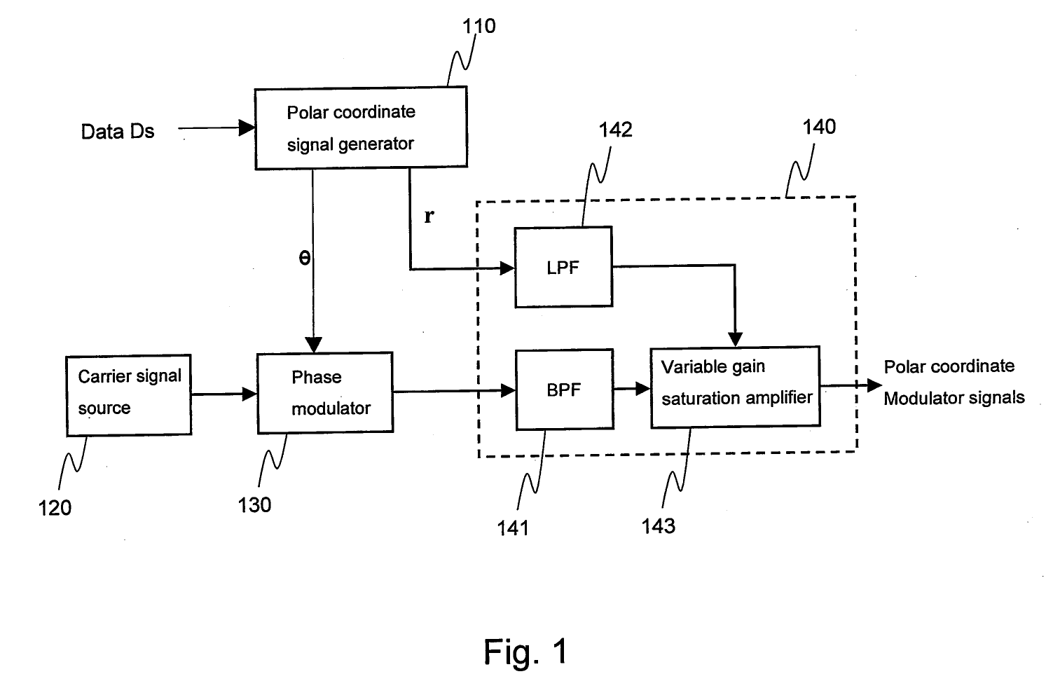

### DETAILED DESCRIPTION OF THE PREFERRED EMBODIMENT

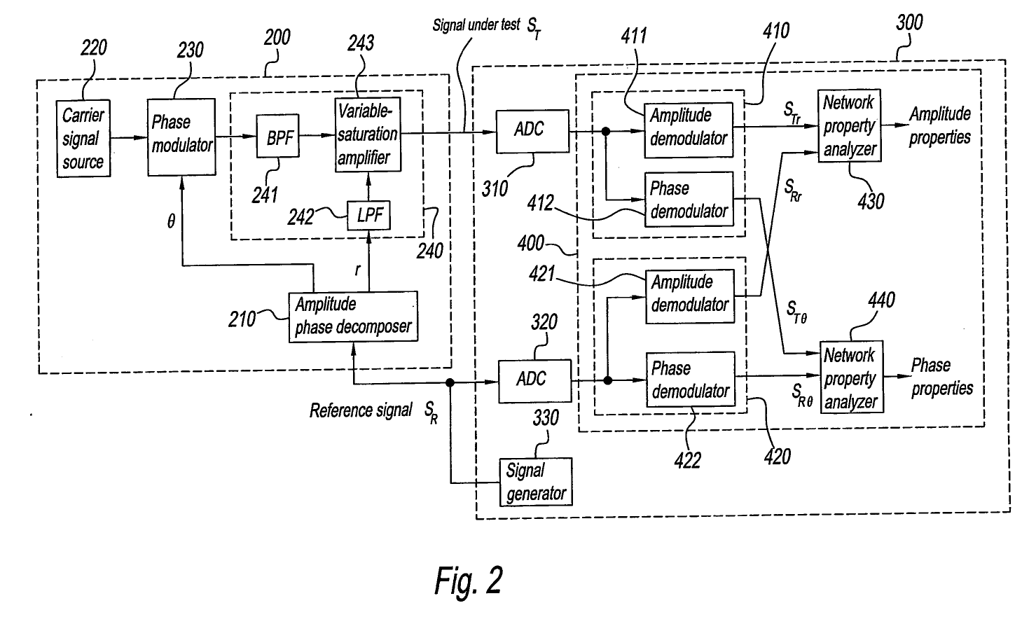

Embodiments of the present invention will now be described while referring to the attached drawings. The first embodiment of the present invention is an electronic measuring apparatus 300. Refer to FIG. 2. FIG. 2 is a drawing showing a signal generator 200, which is the device under test, and the electronic measuring apparatus 300. In the figure, a reference signal S_{R} is applied to signal generator 200 and the output signals of signal generator 200 are applied to electronic measuring apparatus 300. A device under test the signal generator 200 will be briefly described first and then an electronic measuring apparatus 300 will be described. Device under test 200 comprises an amplitude/phase decomposer 210, a carrier signal source 220, a phase modulator 230, and a polar modulation amplifier 240. Amplitude/phase decomposer 210 is an apparatus for decomposing the applied reference signal S_{R} into an amplitude component r and a phase component θ and for outputting those components. Carrier signal source 220 is the apparatus for generating sine wave signals of constant amplitude. The output signals of carrier signal source 220 are phase modulated by phase component θ at phase modulator 230 and further amplitude modulated by the amplitude component r at polar modulation amplifier 240. Polar modulation amplifier 240 comprises a band-pass filter 241, a low-pass filter 242, and a variable-gain saturation amplifier 243. Band pass filter 241 optimizes the output signals of phase modulator 230. Low-pass filter 242 optimizes the amplitude component r. The output signals of band-pass filter 241 are amplified by variable-gain saturation amplifier 243. The gain of variable-gain saturation amplifier 243 is controlled by the output signals of low-pass filter 242.

The structure of electronic measuring apparatus 300 will now be described. Electronic measuring apparatus 300 comprises an analog-digital converter 310, an analog-digital converter 320, a reference signal generator 330, and a processor 400. The analog-digital converters are referred to hereafter as ADCs. ADC 310 is an apparatus for analog-digital conversion of a signal under test S_{T}, which is the output of device under test 200, and outputs the conversion results to processor 400. Reference signal generator 330 is the apparatus for generating reference signals S_{R}. ADC 320 is an apparatus for analog-digital conversion of the reference signal S_{R}, which is the output of device under test 200, and outputs the conversion results to processor 400. Processor 400 is a processor with numeric processing capability, such as a CPU, MPU, RISC, or DSP. As long as it functions in the same way as a CPU, and the like, processor 400 can also be an FPGA, ASIC, and similar devices. Processor 400 functions as an amplitude/phase decomposer 410, an amplitude/phase decomposer 420, a network analyzer 430, and a network analyzer 440 by executing a program that is not illustrated.

Amplitude/phase decomposer 410 and amplitude/phase decomposer 420 resolve an input signal into an amplitude component (amplitude signal) and a phase component (phase signal). Amplitude/phase decomposer 410 comprises an amplitude demodulator 411 and a phase demodulator 412 for amplitude/phase resolution. Amplitude demodulator 411 amplitude demodulates the signal under test S_{T} that is input to amplitude/phase decomposer 410; it thereby generates an amplitude demodulated signal S_{Tr}, which is the amplitude component of signal under test S_{T}; and it outputs this amplitude demodulated signal S_{Tr}. Phase demodulator 412 phase demodulates the signal under test S_{T}; it thereby generates a phase demodulated signal S_{Tθ}, which is the phase component of signal under test S_{T}; and it outputs this phase demodulated signal S_{Tθ}. Amplitude/phase decomposer 420 comprises an amplitude demodulator 421 and a phase demodulator 422 for amplitude/phase resolution. Amplitude demodulator 421 amplitude demodulates the reference signal S_{R} that is input to amplitude/phase decomposer 420; it thereby generates a reference amplitude signal S_{Rr}, which is the amplitude component of reference signal under test S_{R}; and it outputs this reference amplitude signal S_{Rr}. Phase demodulator 422 phase demodulates the reference signal under test S_{R}; it thereby extracts a reference phase signal S_{Rθ}, which is the phase component of reference signal under test S_{R}; and it outputs this reference phase signal S_{Rθ}. Amplitude demodulator 411 and amplitude demodulator 421 are the same demodulation system. Moreover, phase demodulator 412 and phase demodulator 422 are the same demodulation system. Network analyzer 430 and network analyzer 440 analyze network properties based on the two input signals.

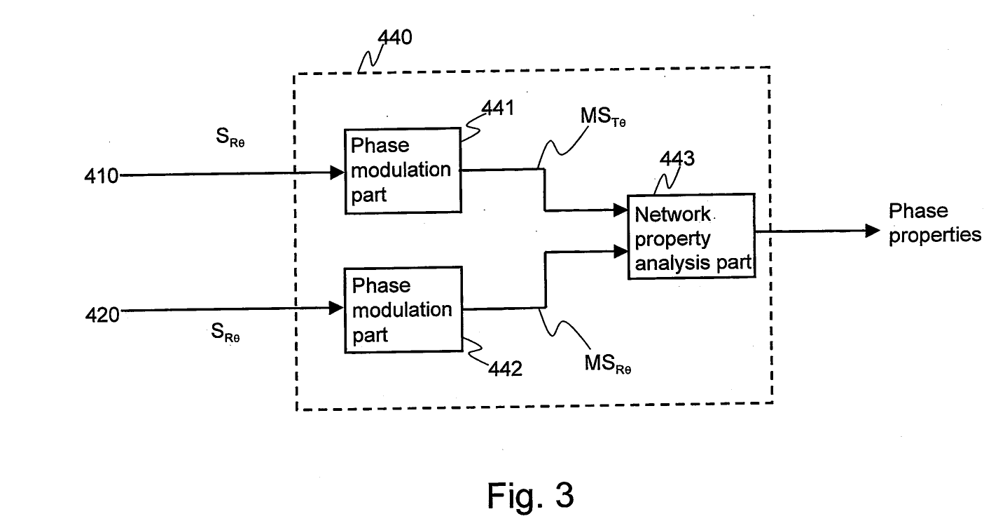

Refer now to FIG. 3. FIG. 3 is a block diagram showing the internal structure of network analyzer 440. Network property analyzer 440 comprises a phase modulation part 441, a phase modulation part 442, and a network analysis part 443. Phase modulation part 441 and phase modulation part 442 are employed for remodulation of input signals. The modulation system of phase modulation part 441 is paired up with the demodulation system of phase demodulator 412. The modulation system of phase modulation part 442 is paired up with the demodulation system of phase demodulator 422. Consequently, the modulation system of phase modulation part 441 and that of phase modulation part 442 are the same modulation systems. Network property analysis part 443 analyzes the network properties based on the output signals of phase demodulator 412 and phase demodulator 422.

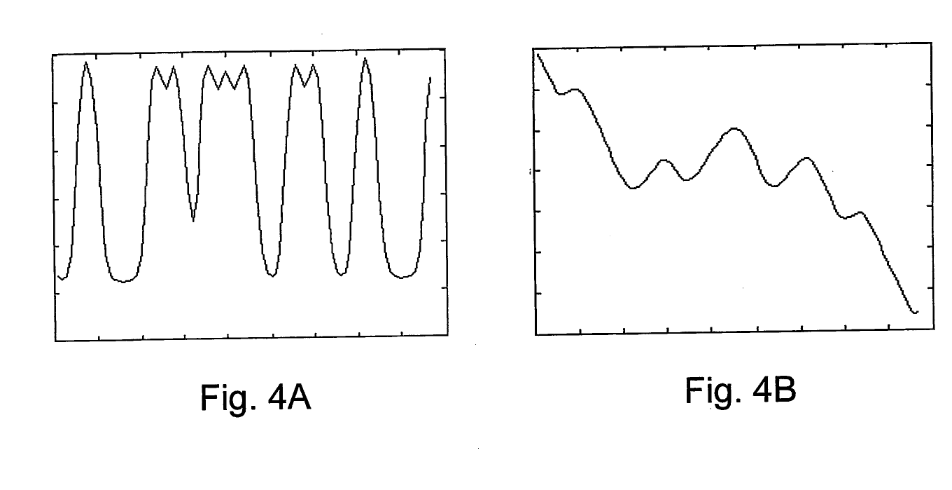

The structure of electronic measuring apparatus 300 was described above. The operation of electronic measuring apparatus 300 will now be described. Return to FIG. 2. First, reference signal generator 330 generates reference signal S_{R}, which is a modulated signal. Reference signal S_{R} is generated depending on the input specifications of the device under test. For instance, when it is input to device under test 200, reference signal S_{R} is generated by a polar modulation system, an Orthogonal modulation system, and similar systems. Next, amplitude demodulated signal S_{Tr} and phase demodulated signal S_{Tθ} are generated at amplitude/phase decomposer 410 from the signal under test S_{T} that has been analog-digital converted by ADC 310. On the other hand, reference amplitude signal S_{Rr} and reference phase signal S_{Rθ} are generated at amplitude-phase decomposer 420 from reference signal S_{R} that has been analog-digital converted by ADC 320. By way of reference, FIG. 4A shows the waveform of reference amplitude signal S_{Rr} and FIG. 4B shows the waveform of reference phase signal S_{Rθ}. The y-axis in FIGS. 4A and 4B indicates the signal amplitude and the x-axis shows time.

Refer to FIG. 2 once more. Amplitude demodulated signal S_{Tr} and corresponding reference amplitude signal S_{Rr} are analyzed by network property analyzer 430. Network property analyzer 430 finds the complex spectrum or the power spectrum of amplitude demodulated signal S_{Tr} and reference amplitude signal S_{Rr} and compares the resulting two spectra. Network property analyzer 430 thereby can analyze the network properties of the path inside device under test 200 related to the amplitude component of the polar modulated signals. Network property analyzer 430 specifically can analyze the network properties between amplitude/phase decomposer 210 and variable-gain saturation amplifier 243. Consequently, the network properties of low-pass filter 242 can be analyzed. Moreover, phase demodulated signal S_{Tθ} and reference phase signal S_{Rθ} are analyzed by network property analyzer 440. Network property analyzer 440 remodulates phase demodulated signal S_{Tθ} and reference phase signal S_{Rθ} individually and analyzes network properties based on a remodulated phase demodulated signal MS_{Tθ} and a remodulated reference phase signal MS_{Rθ}. Network property analysis part 443 finds the complex spectrum or power spectrum of remodulated phase demodulated signal MS_{Tθ} and remodulated reference phase signal MS_{Rθ} and compares the resulting two spectra. Network property analyzer 440 thereby can analyze the network properties of the path inside device under test 200 relating to phase modulation for generation of polar modulated signals. Network property analyzer 430 can specifically analyze the network properties between phase modulator 230 and variable-gain saturation amplifier 243. Consequently, the network properties of band-pass filter 241 can be analyzed. Network property analyzer 430 and network property analysis part 443 can also be such that the network properties are analyzed not only by a method that uses the above-mentioned spectrum comparison (frequency domain method), but also by a method whereby impulse response is identified (time domain method) such as cited in JP Unexamined Patent Application (Kokai) 2004-361,170.

However, there are cases in which a time difference is produced between signal under test S_{T} and reference signal S_{R}. This time difference is attributed, for instance, to the length of the electrical path between signal generator 330 and amplitude/phase decomposer 210, or the processing time of the amplitude/phase decomposer. This time difference applies a linear phase that is proportional to frequency to the analysis results of network property analyzer 440. This time difference must be taken into consideration when measuring and compensating for the length of the electrical path inside device under test 200, but it can be disregarded when the properties of filters and similar components are being measured. For example, this time difference is unrelated to the frequency-amplitude properties and merely applies a gradient to the frequency-phase properties when analyzing the network properties of a filter. Consequently, it is possible to thoroughly identify the nonlinear phase properties of a filter.

Network property analysis part 443 can analyze phase demodulated signal S_{Tθ} and reference phase signal S_{Rθ} in place of the remodulated signals. In this case, the network properties of the path inside device under test 200 related to the phase component of the polar modulated signals, that is, the network properties between phase modulator 230 and amplitude/phase decomposer 210, can be analyzed. Moreover, network property analyzer 430 can remodulate amplitude demodulated signal S_{Tr} and reference amplitude signal S_{Rr} individually and analyze the network properties for remodulated results. In this case, it is possible to analyze the network properties of the path inside the device under test related to amplitude modulation for the generation of polar modulated signals. For instance, when circuit elements are temporarily connected to the subsequent stage of variable-gain saturation amplifier 243 of polar modulation amplifier 240, the network properties of the circuit elements can be analyzed. The above description concerns the first embodiment.

The amplitude component and the phase component are analyzed here in the first embodiment, but it is also possible to analyze the amplitude component and the frequency component. This is because phase modulation and frequency modulation are both called angle modulation and have properties that can be mutually converted. Conversion from phase modulation to frequency modulation is conducted as described below. Phase demodulator 412 and phase demodulator 422 in FIG. 2 can be changed to frequency demodulators. As a result of this conversion, a frequency demodulated signal is obtained by the frequency demodulation of the signal under test S_{T} and a reference frequency signal is obtained by the frequency modulation of the reference signal S_{R}. When frequency demodulated signals and reference frequency signals are analyzed by a network property analyzer in place of phase components, it is possible to analyze the network properties of the path inside device under test 200 related to the frequency component of polar modulated signals.

Moreover, it is also possible to construct the functional elements inside processor 400 in the first embodiment, for instance, the amplitude/phase decomposer and network property analyzers, with actual hardware rather than virtually realizing these elements by executing programs. And vice-versa, reference signal generator 330 in the first embodiment can also be realized inside processor 400.

ADC 310 and ADC 320 in the first embodiment are devices such that input signals are directly analog-digital converted, but they can also be such that a frequency converter is disposed in front of at least one of devices ADC 310 and ADC 320 in order to change the frequency band that is used.

Reference signals S_{R} can also be supplied from outside electronic measuring apparatus 300 in the first embodiment. Moreover, reference signals S_{R} can be generated inside electronic measuring apparatus 300, and other reference signals can be supplied to device under test 200 from the outside. In this case, electronic measuring apparatus 300 can generate reference signals S_{R} from signals under test S_{T} by demodulating and modulating signals under test S_{T} as cited in JP Unexamined Patent Application (Kokai) 2004-361,170.

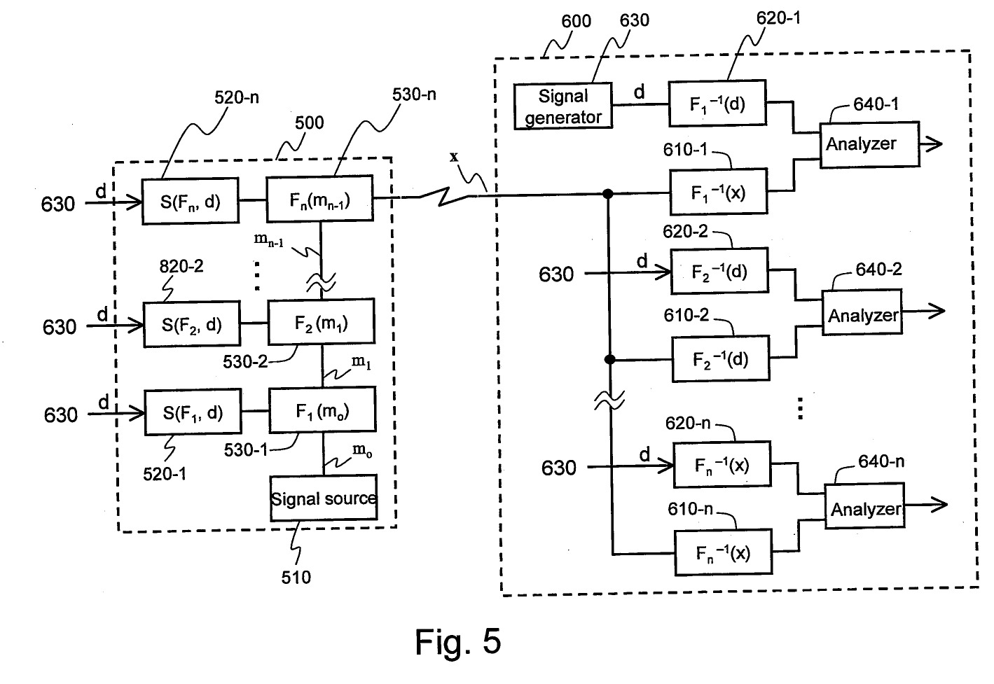

Moreover, the present invention can be generalized as follows. Refer to FIG. 5. FIG. 5 is a drawing showing a modulated signal generator 500 and an electronic measuring apparatus 600. Electronic measuring apparatus 600 measures signals generated by modulated signal generator 500 which is the device under test, and analyzes the network properties of modulated signal generator 500. Modulated signal generator 500 comprises a signal source 510 that produces the carrier signal, n number of signal sources (520-1 to n), and n number of modulators (530-1 to n). n is an integer of one or greater. Signal sources (520-1 to n) are apparatuses for generating signals S (F₁ to Fₙ, d) based on related modulation systems (F₁ to Fₙ) and a reference signal d. Modulators (530-1 to n) use modulation systems that will not interfere with one another. The phrase “will not interfere with one another” means that, for instance, the signals that modulator (530-1) allows to ride on the carrier are not affected by the other modulator (530-2), and only signals corresponding to signal S (F₁, d) can be demodulated by the demodulation system that is paired up with the modulation system of modulator (530-1). Output signals mo of signal source 510 are modulated in succession by modulators (530-1 to n) and sent to electronic measuring apparatus 600. m₁, m₂, . . . mₙ₋₁ indicate the output signals of modulators 530-1, 530-2, . . . 530-(n−1), respectively. It should be noted that signal sources (520-1 to n) can be replaced by a signal generator that performs 1 to n functions. Similarly, modulators (530-1 to n) can be replaced by a modulator that performs 1 to n functions.

Electronic measuring apparatus 600 comprises n number of demodulators (610-1 to n), n number of demodulators (620-1 to n), a reference signal generator 630, and n number of network property analyzers (640-1 to n). Demodulators (610-1 to n) and demodulators (620-1 to n) perform demodulation by a system that pairs up with the modulation system of modulators (530-1 to n), respectively. F₁⁻¹ to Fₙ⁻¹ represent the demodulation systems that are paired up with F₁ to Fₙ, respectively. Reference signals d are modulated signals and are output from reference signal generator 630. Although not illustrated, reference signal generator 630 is electrically connected with each signal source (520-1 to n) and demodulator (620-1 to n) in order to supply reference signals d. Each network property analyzer (640-1 to n) references output signals F₁⁻¹ to Fₙ⁻¹ (x) of related demodulators (610-1 to n) and output signals F₁⁻¹ to Fₙ⁻¹(d) of related demodulators (620-1 to n), respectively; finds the network properties by the time domain method or frequency domain method; and outputs the results. If remodulation has not been performed inside each network property analyzer (640-1 to n), the results that are obtained show the network properties of the path between each signal source (520-1 to n) and modulator (530-1 to n). On the other hand, if remodulation has been performed inside of each network property analyzer (640-1 to n), the results that are obtained show the network properties of the path between each modulator (530-1 to n). It goes without saying that the changes that were previously discussed also apply to this expanded embodiment.

What is claimed is:

1. A network property analysis method for analyzing the network properties of a device under test, said method comprising:
applying reference modulated signals to the device under test or for generating reference modulated signals from the output signals of the device under test;
generating each component of the output signals from the output signals of the device under test;
generating each component of the reference modulated signals from the reference modulated signals; and
analyzing the network properties of the device under test based on the components of the output signals and the components of the corresponding reference modulated signals.

2. A network property analysis method for analyzing the network properties of a device under test, said method comprising:
applying reference modulated signals to the device under test or for generating reference modulated signals from the output signals of the device under test;
demodulating the output signals of the device under test by the respective system of N number of one or more different demodulation systems to obtain N number of demodulated signals, which are the demodulation results;
demodulating the reference modulated signals by the respective system of said N number of demodulation systems to obtain N number of demodulated signals, which are the demodulation results; and
analyzing the network properties of the device under test based on the demodulated signals of the output signals and the demodulated signals of the reference demodulated signals originating from the same demodulation system.

3. The method according to claim 2, wherein said analyzing comprises analyzing the network properties of the device under test based on the results of modulation by the modulation system that is paired up with the demodulation system related to the demodulated signals of the output signals and the results of modulation by the modulation system that is paired up with the demodulation system related to the demodulated signals of the reference modulated signals for at least one demodulation system.

4. A network property analysis method for analyzing the network properties of a device under test, said method comprising:
applying reference modulated signals to a device under test or for generating reference modulated signals from the output signals of the device under test;
demodulating amplitude of output signals of the device under test and for obtaining amplitude demodulated signals, which are the amplitude component of the output signals;
demodulating phase of the output signals and for obtaining phase demodulated signals, which are the phase component of the output signals;
demodulating amplitude of the reference modulated signals and for obtaining reference amplitude signals, which are the amplitude component of the reference signals;
demodulating phase of the reference modulated signals and for obtaining reference phase signals, which are the phase component of the reference signals;
analyzing the network properties of the device under test based on the amplitude demodulated signals and the reference amplitude signals; and
analyzing the network properties of the device under test based on the phase demodulated signals and reference phase signals.

5. The method according to claim 4, wherein said step of analyzing the network properties of the device under test based on the phase demodulated signals and the reference phase signals comprises analyzing the network properties of the device under test based on the results of modulating said phase demodulated signals by the phase modulation system that is paired up with the phase demodulation system related to said phase demodulated signals and the results of modulating said reference phase signals by said phase modulation system.

6. An apparatus for network property analysis for analyzing the network properties of a device under test, said apparatus comprising:
a first signal generator for applying reference modulated signals to the device under test or for generating reference modulated signals from the output signals of the device under test;
a second signal generator for generating each component of the output signals from the output signals of the device under test;
a third signal generator for generating each component of the reference modulated signals from the reference modulated signals, wherein said second and third signal generators can be either the same or different signal generators; and
a network analyzer for analyzing the network properties of the device under test based on the components of the output signals and the components of the corresponding reference modulated signals.

7. An apparatus for network property analysis for analyzing the network properties of a device under test, said apparatus comprising:
a signal generator for applying reference modulated signals to the device under test or for generating reference modulated signals from the output signals of the device under test;
a first demodulator for demodulating the output signals of the device under test by the respective system of N number of one or more different demodulation systems to obtain N number of demodulated signals, which are the demodulation results;
a second demodulator for demodulating the reference modulated signals by the respective system of said N number of demodulation systems to obtain N number of demodulated signals, which are the demodulation results, wherein said first and second demodulators can be either the same or different demodulators; and
a network analyzer for analyzing the network properties of the device under test based on the demodulated signals of the output signals and the demodulated signals of the reference demodulated signals originating from the same demodulation system.

8. The apparatus according to claim 7, wherein said network analyzer analyzes the network properties of the device under test based on the results of modulation by the modulation system that is paired up with the demodulation system related to the demodulated signals of the output signals and the results of modulation by the modulation system that is paired up with the demodulation system related to the demodulated signals of the reference modulated signals for at least one demodulation system.

9. An apparatus for network property analysis for analyzing the network properties of a device under test, said apparatus comprising:
a signal generator for applying reference modulated signals to a device under test or for generating reference modulated signals from the output signals of the device under test;
a first demodulator for amplitude demodulation of output signals of the device under test and for obtaining amplitude demodulated signals, which are the amplitude component of the output signals;
a second demodulator for phase demodulation of the output signals and for obtaining phase demodulated signals, which are the phase component of the output signals;
a third demodulator for amplitude demodulation of the reference modulated signals and for obtaining reference amplitude signals, which are the amplitude component of the reference signals;
a fourth demodulator for phase demodulation of the reference modulated signals and for obtaining reference phase signals, which are the phase component of the reference signals, wherein said first, second, third and fourth demodulators can be either the same or different demodulators;
a first network analyzer for analyzing the network properties of the device under test based on the amplitude demodulated signals and the reference amplitude signals; and
a second network analyzer for analyzing the network properties of the device under test based on the phase demodulated signals and reference phase signals.

10. The apparatus according to claim 9, wherein said second network analyzer analyzing the network properties of the device under test based on the phase demodulated signals and the reference phase signals analyzes the network properties of the device under test based on the results of modulating said phase demodulated signals by the phase modulation system that is paired up with the phase demodulation system related to the phase demodulated signals and the results of modulating said reference modulated signals by said phase modulation system.
